(19) United States
(12) Patent Application Publication
(10) Pub. No.: US 2006/0139074 A1
(43) Pub. Date: Jun. 29, 2006

(54) Charge pump DC / DC converter

(76) Inventor: Hiroki Doi, Yamatokoriyama-shi (JP)

Correspondence Address: HARNESS, DICKEY & PIERCE, P.L.C., P.O.BOX 8910, RESTON, VA, 20195, US

(21) Appl. No.: 11/313,648

(22) Filed: Dec. 22, 2005

(30) Foreign Application Priority Data
Dec. 24, 2004 (JP) 2004-374866

(51) Int. Cl. H03L 7/06

(52) U.S. Cl. 327/157

(57) ABSTRACT

The present invention is a charge pump circuit provided as a charge pump DC/DC circuit for reducing the in-rush current in an initial operation of a charge pump operation. The charge pump DC/DC converter is realized using a conventional charge pump SW circuit, without any modification to the charge pump SW circuit portion. In the initial operation of the charge pump operation, a predetermined pre-set voltage is inputted that increases with time. With a feedback circuit provided in the charge pump DC/DC converter, charging of output capacitor C of power supply voltage VIN is allowed if the output voltage is below the pre-set voltage, and is disallowed if the output voltage exceeds the pre-set voltage. By setting a pattern of increase of the pre-set voltage during manufacture or use, the rate of increase of the output voltage can be reduced.

This Nonprovisional application claims priority under 35 U.S.C. § 119(a) on Patent Application No. 374866/2004 filed in Japan on Dec. 24, 2004, the entire contents of which are hereby incorporated by reference.

### FIELD OF THE INVENTION

The present invention relates to DC/DC converters for converting a DC voltage into a predetermined DC voltage, and particularly to charge pump DC/DC converters.

### BACKGROUND OF THE INVENTION

FIG. 25 illustrates a circuit as one example of a conventional charge pump DC/DC converter. The charge pump circuit shown in FIG. 25 is a voltage doubler, producing an output voltage which is twice the power voltage VIN. As shown in FIG. 25, a DC/DC converter 80 includes a charge pump SW circuit 81, a driving circuit 82, an oscillating circuit 83 for supplying a clock signal to the driving circuit 82, a charging fly capacitor C81, and an output capacitor C82. The charge pump SW circuit 81 includes MOS transistors Q81 through Q84, each of which is turned on and off under control of the driving circuit 82. The notation “SW” will be used to refer to a switch, unless otherwise noted.

In stepping up the voltage, the charge pump circuit repeats the following operation. First, only the MOS transistors Q82 and Q84 are turned on to charge the fly capacitor C81 to VIN. At the next timing of the oscillating circuit 83, the MOS transistors Q82 and Q84 are turned off and the MOS transistors Q81 and Q83 are turned on, so as to apply input voltage VIN to the charged voltage of the fly capacitor C81. The stepped-up voltage is then used to charge the output capacitor C82 and thereby obtain an output voltage.

As shown in FIG. 26, in response to the power voltage VIN, a charge current flows into the fly capacitor C81 and the output capacitor C82 via the parasitic diodes of the MOS transistors Q81 and Q82, and a voltage slightly below VIN appears at an output terminal 85. FIG. 27 shows a power current (DC/DC converter side) flowing out of the bypass capacitor C83 to DC/DC converter 80, and FIG. 28 shows a power current (power supply side) flowing into a VIN-GND bypass capacitor C83 beside DC/DC converter 80. At the start of the charge pump operations following the initial standby state, a large charge current is flown at the timing of SW operations, until the output capacitor C82 is sufficiently charged. As the in-rush current flowing into the VIN-GND bypass capacitor C83, the average current appears during the initial operation as shown in FIG. 28.

A problem of the conventional DC/DC converter, then, is that the in-rush current is flown at an early stage of the step-up operation before the fly capacitor C81 and the output capacitor C82 are sufficiently charged. This causes adverse effects on other devices.

The following will describe this in more detail. The primary components of the charge pump circuit are the charge pump SW circuit 81, the driving circuit 82, and the oscillating circuit 83. The driving circuit 82 generates first and second control signals 87 and 88 based on clock signal waveforms produced in the oscillating circuit 83, and the first and second control signals 87 and 88 are used to drive the charge pump SW circuit 81.

The circuit shown in FIG. 29 is generally known as a doubler, and it includes two capacitors (C81, C82), and four switches SW (Q81, Q82, Q83, Q84). The doubler has two switching states.

In the first state, the oscillating circuit 83 supplies a clock signal 86 to the driving circuit 82, and the first and second control signals 87 and 88 become low (L) level and high (H) level, respectively, to charge the fly capacitor 81. Here, the fly capacitor C81 stores charge equivalent to VIN.

In the second state, the first and second control signals 87 and 88 have inverted levels. Here, the MOS transistors Q82 and Q84 are turned off, and the MOS transistors Q81 and Q83 are turned on. As a result, the fly capacitor C81 is connected to the output capacitor C82 with the VIN level added to the stored charge equivalent to VIN. As a result, the output terminal 85 outputs VIN increased by two fold.

Under normal conditions, only the amount of charge dissipated by the load on the output terminal needs to be restored according to the foregoing operation. However, at power-up, the amount of stored charge in the smoothing capacitor C82 is not sufficient, and the capacitors which differ from each other by the amount of stored charge are shorted during the charge pump operation. As a result, a large current is flown transiently. Under normal conditions, such a large current is smoothed by the bypass capacitor C83 interposed between VIN and GND. However, at power-up where a large current is flown repeatedly during a short time period, a current I89 that flows between the power supply and the bypass capacitor from VIN becomes considerably large. Such a considerably large current that flows at power-up is known as in-rush current.

Since the charge pump circuit is the power supply, the output terminal 85 is connected to another circuit. The input side (primary power supply VIN) is also connected to another circuit 90.

In the case where such a circuit 90 shares the power supply VIN, there is a potential risk that the large in-rush current causes a voltage drop at VIN due to the wire resistance. This may lead to malfunction of the circuit 90.

Further, if the current 189 far exceeds the acceptable current range of the wire, the power line may itself be destroyed.

As a means for avoiding such adverse effects of the in-rush current on other devices, there has been proposed a circuit as disclosed in Japanese Laid-Open Patent Publication No. 219634/2003 (Tokukai 2003-219634; published on Jul. 31, 2003) (hereinafter, “Patent Document 1”). FIG. 30 illustrates the circuit.

The circuit as disclosed in Patent Document 1 includes a pre-charge circuit 93 and a first in-rush current avoiding circuit 92. With these SW switching circuits, the performance of the charge pump SW is intentionally reduced (with the addition of transistors Q5 and Q6) during the operation, in order to solve the foregoing problem.

However, the method as disclosed in the foregoing Patent Document 1 requires reconstruction of the charge pump SW circuit 91. The method also requires SW switching signals in addition to the control circuit. Adding SW in the charge pump portion increases a leak current from the capacitors. This reduces the efficiency of the DC/DC converter. Further, since the charge pump SW needs to incorporate an additional control structure, great care must be taken in determining the circuit layout.

### SUMMARY OF THE INVENTION

The present invention was made in view of the foregoing problems, and an object of the present invention is to provide a charge pump DC/DC converter that can reduce the in-rush current at power-up, without the need to change the charge pump SW circuit portion or a conventional control method.

In order to achieve the foregoing object, a charge pump DC/DC converter according to the present invention includes: a charge pump for charging an output capacitor to produce an output voltage; and a charging control circuit for allowing/disallowing charging of the output capacitor in an initial operation of a charge pump operation based on a predetermined pre-set voltage that increases with time and reaches a target output voltage level of the charge pump DC/DC converter by the time the initial operation of the charge pump operation is finished, wherein the charging control circuit allows charging of the output capacitor if the output voltage is below the pre-set voltage, and disallows charging of the output capacitor if the output voltage is above the pre-set voltage.

With this configuration, in the initial operation of the charge pump operation, charging of the output capacitor is allowed if the output voltage is below the pre-set voltage. As a result, the output voltage increases. If the output voltage exceeds the pre-set voltage, charging of the output capacitor is disallowed. As a result, the output voltage is suspended. The pre-set voltage increases with time.

In a conventional charge pump DC/DC converter, the output voltage is increased continuously, irrespective of the current output voltage. In contrast, with the foregoing configuration, the output voltage is allowed to increase while it is below the pre-set voltage, and the output voltage is suspended when it exceeds the current value of the pre-set voltage. Then, when the pre-set voltage exceeds the current output voltage as a result of predetermined increase, the output voltage is allowed to increase again. In this manner, the output voltage is increased and suspended repeatedly.

Thus, by setting a pattern of increase of the pre-set voltage during manufacture or use, the rate of increase of the output voltage can be reduced. In this way, the in-rush current in the initial operation state of the charge pump operation can be reduced using a conventional charge pump DC/DC converter, without any modification to the circuit (charge pump SW (switch) circuit) portion provided with an output capacitor and a switching element for switching charging/discharging of the output capacitor in response to an inputted control signal (clock signal) for the output capacitor.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is a block diagram showing an exemplary structure of a charge pump DC/DC converter according to the present invention.

FIG. 2 is a circuit diagram showing an exemplary structure of a charge pump SW circuit.

FIG. 3 is a circuit diagram representing a relationship between VIN and wire resistance.

FIG. 4 is a circuit diagram showing an exemplary structure of a feedback circuit.

FIG. 5 is a circuit diagram showing an exemplary structure of a reference voltage generating circuit.

FIG. 6 is a circuit diagram showing an exemplary structure of a control section of a driving circuit.

FIG. 7 is a circuit diagram showing another exemplary structure of the control section of the driving circuit.

FIG. 8 is a graph representing an example of waveforms of output voltage and pre-set voltage.

FIG. 9 is a graph representing an example of a waveform of a power supply current flowing out of a bypass capacitor.

FIG. 10 is a graph representing an example of a waveform of a power supply current flowing into the bypass capacitor.

FIG. 11 is a graph representing an example of a voltage waveform of a clock signal.

FIG. 12 is a graph representing an example of a voltage waveform of a first control signal.

FIG. 13 is a graph representing an example of a waveform of a second control signal.

FIG. 14 is a graph representing an example of waveforms of output voltage, pre-set voltage, and deciding voltage.

FIG. 15 is a graph representing an example of a waveform of a clock signal.

FIG. 16 is a graph representing an example of a voltage waveform of the first control signal.

FIG. 17 is a graph representing an example of a voltage waveform of the second control signal.

FIG. 18 is a graph representing examples of waveforms of output voltage, pre-set voltage, and deciding voltage.

FIG. 19 is a graph representing an example of a voltage waveform of a clock signal.

FIG. 20 is a graph representing an example of a voltage waveform of the first control signal.

FIG. 21 is a graph representing an example of a voltage waveform of the second control signal.

FIG. 22 is a circuit diagram showing an exemplary structure of a reference voltage generating circuit.

FIG. 23 is a circuit diagram showing another exemplary structure of the reference voltage generating circuit.

FIG. 24 is a graph representing an example of waveforms of output voltage and pre-set voltage.

FIG. 25 is a circuit diagram showing an exemplary structure of a conventional charge pump DC/DC converter.

FIG. 26 is a graph representing an example of a waveform of a conventional output voltage.

FIG. 27 is a graph representing an example of a waveform of a power supply voltage flowing out of a conventional bypass capacitor.

FIG. 28 is a graph representing an example of a waveform of a power supply voltage flowing into the conventional bypass capacitor.

FIG. 29 is a circuit diagram showing an exemplary structure of a conventional charge pump DC/DC converter.

FIG. 30 is a circuit diagram showing an exemplary structure of a conventional charge pump DC/DC converter.

### DESCRIPTION OF THE EMBODIMENTS

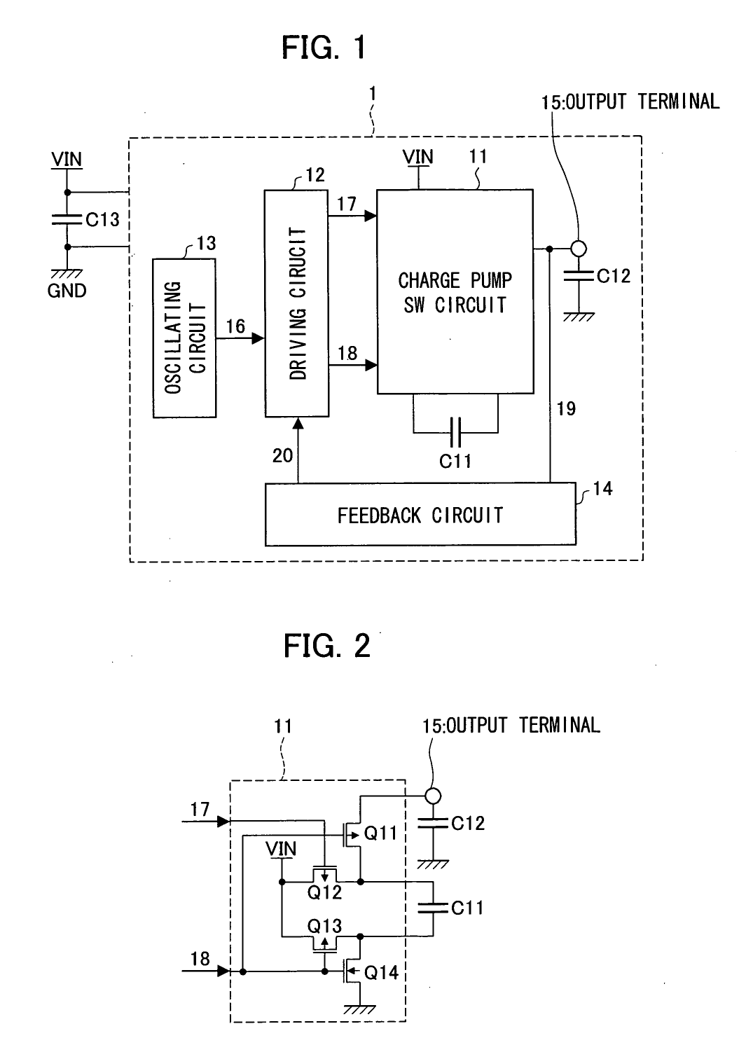

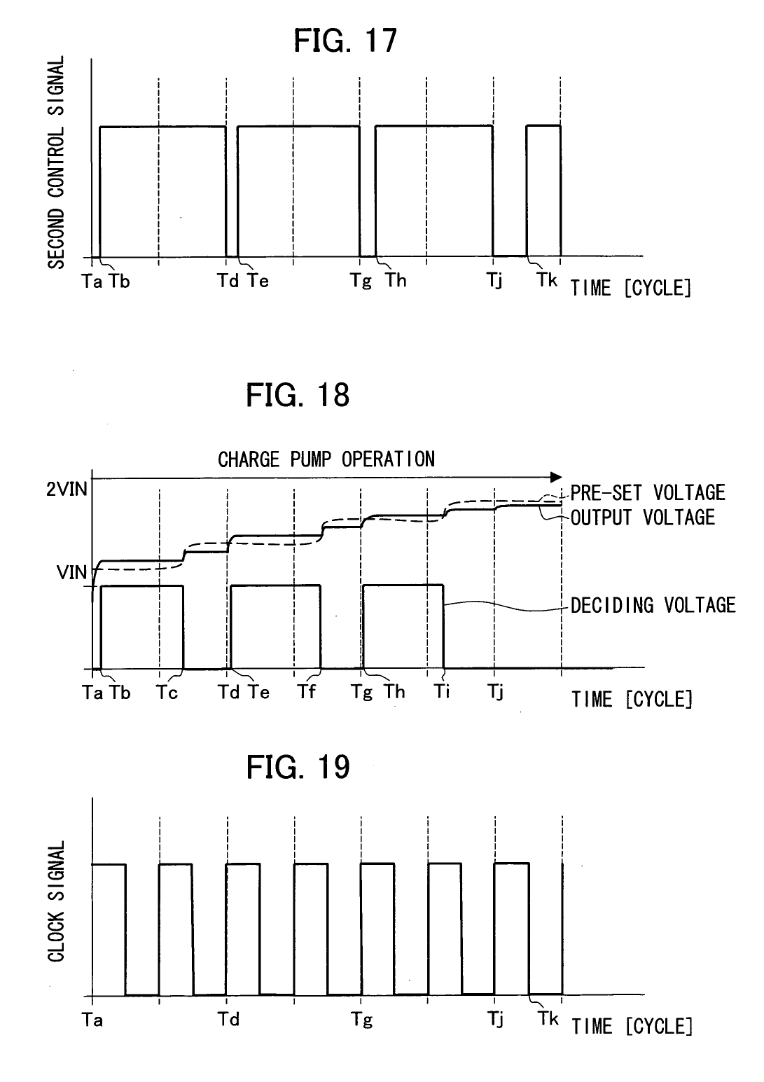

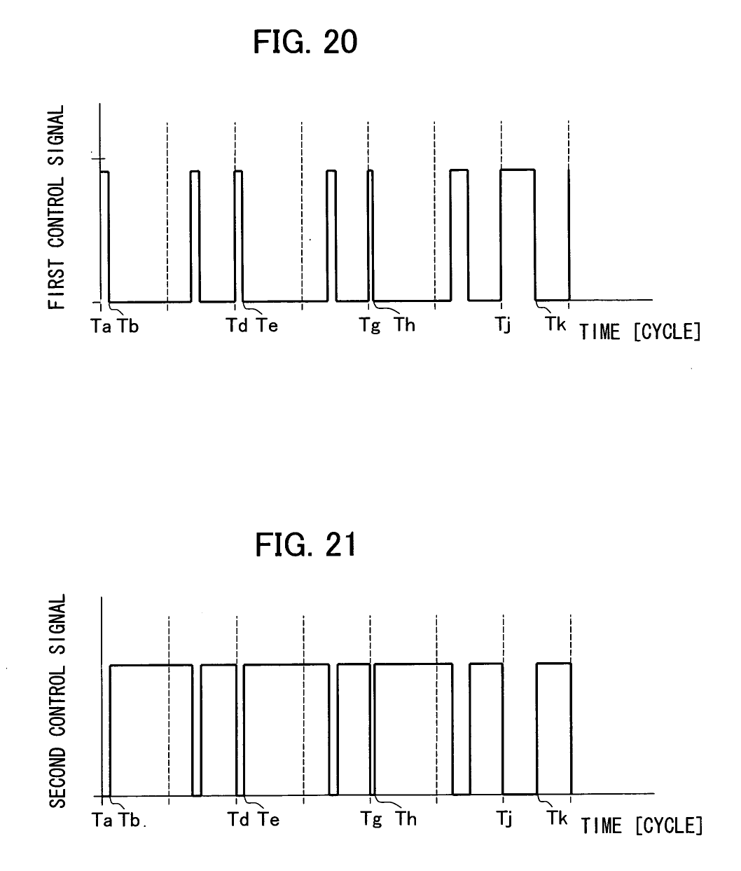

The following will describe one embodiment of the present invention with reference to FIGS. 1 through 24.

The present embodiment is a DC/DC converter for performing a step-up operation according to the charge pump system. As described herein, the DC/DC converter is used in small electrical devices to step-up a power voltage. In the converter of the embodiment, capacitors and voltages applied thereto are controlled in pulses, and therefore a large current is transiently flown at the switching of pulses for example. This is particularly prominent in the initial state of operation (at power-up) and may lead to system destruction. In order to avoid such problems, an initial standby state has conventionally been provided at the start of power-up. The initial standby state is followed by the charge pump operation. The present embodiment avoids a considerably large current, known as an in-rush current, that flows during the charge pump operation.

Specifically, in the present embodiment, the charge pump operation for stepping up the voltage is performed in such a manner that, when monitoring and varying the output (stepped-up) voltage, the output level is gradually increased by controlling the pulse voltage and its applied timing to a plurality of capacitors.

As illustrated in FIG. 1, a charge pump circuit (charge pump DC/DC converter) 1 includes a charge pump SW circuit 11, a driving circuit 12, an oscillating circuit 13 for supplying a clock signal 16 to the driving circuit 12, and a feedback circuit (charging control circuit) 14 for monitoring an output voltage 19 outputted from an output terminal 15 and supplying a signal (deciding voltage 20) to the driving circuit 12. Indicated by reference numeral C11 is a fly capacitor that is charged with power voltage VIN, and C12 is a smoothing capacitor, serving as an output capacitor, that is charged with C11 and power voltage VIN. A capacitor C13 is generally interposed between a power supply and GND, when using an IC.

FIG. 2 illustrates a structure of the charge pump SW circuit 11. Note that, no further explanation will be made for the switching operation of switches and the subsequent charging operation of C11 and C12, since these operations are the same as those described in the BACKGROUND ART section.

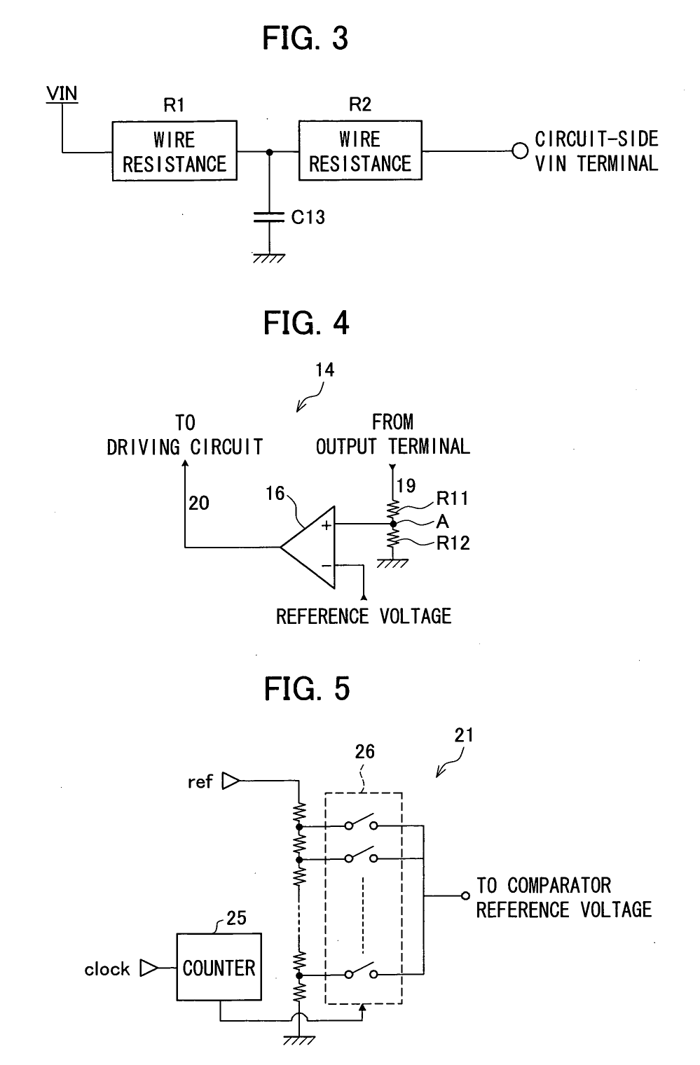

FIG. 3 depicts a relationship between power voltage VIN and wire resistance. As a rule, the wire resistance around IC is negligible. However, it becomes significant under certain circumstances as in the case where there is a flow of in-rush current.

The feedback circuit 14 compares the output voltage 19 with a pre-set voltage (described later), and allows or disallows charging of C12 based on the result of comparison. This will be described later in more detail. FIG. 4 illustrates a structure of the feedback circuit 14. In monitoring the output terminal 15, a comparator 16 outputs H level and enables the driving circuit 12 when the voltage monitored by divided resistors reaches a predetermined voltage (here, a reference voltage used in the feedback circuit 14). In this manner, the feedback circuit 14 monitors the output terminal voltage, and transmits the monitored result to the driving circuit 12 by sending the deciding voltage 20. The reference voltage may be generated in a reference voltage generating circuit 21 (described later) and supplied to the feedback circuit 14.

To describe more specifically, by the provision of divided resistors for example, two voltages are produced: one having a predetermined potential difference (at point A) from the output terminal; and one (reference voltage) having the same potential difference from the pre-set voltage. In this example, resistors R11 and R12 are serially connected to each other between the output terminal 15 and GND. The junction between the resistors R11 and R12 is point A. That is, point A is where there is a predetermined potential difference ΔV from the output terminal.

Here, ΔV=Vout·R11/(R11+R12), and

Va=Vout·R12/(R11+R12)<Vout

where Vout is the output voltage 19, Va is the voltage at point A (voltage used for comparison), ΔV is the potential difference across R11 (=Vout−Va), Vst is the reference voltage, and Vr is the pre-set voltage.

Pre-set voltage Vr=Vst+ΔV=Vst+(Vout−Va).

Here, the reference voltage is increased to raise the pre-set voltage, and the comparator 16 compares the voltage Va at point A with the reference voltage Vst. From the foregoing relations, this is the same as comparing the reference voltage Vst with the pre-set voltage Vr. Alternatively, the output voltage Vout and the pre-set voltage Vr may be compared with each other by directly supplying these voltages to the comparator.

With an arbitrary reference voltage (to be described later), the feedback circuit 14 can set any pre-set voltage. With this control, the voltage can rise gradually at the start of the charge pump operation. Further, at the start of the charge pump operation, the feedback circuit 14 suppresses the driving operation of the charge pump SW circuit 11, so as to suppress the in-rush current in the initial stage of operation.

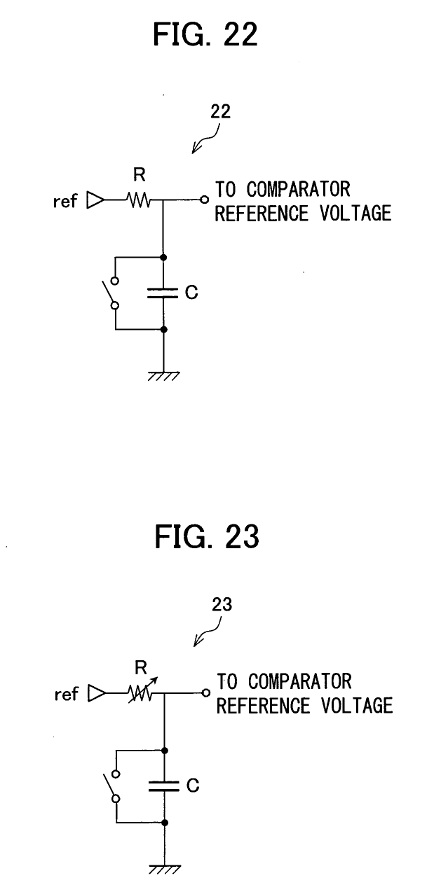

FIG. 5 illustrates an exemplary structure of the reference voltage generating circuit for setting the reference voltage. Other structures of the reference voltage generating circuit will be described later with reference to FIGS. 22 and 23. The reference voltage generating circuit (reference voltage varying and generating circuit) 21 shown in FIG. 5 includes a counter 25 and a selector 26, wherein the counter is used to perform a control operation. Specifically, the reference voltage generating circuit 21 is adapted so that a voltage is set with a group of switches, using a resistor array based on internal reference voltage ref, and that the selector 26 can select a switch that is to be switched on, based on a signal sent from the counter 25, for which voltages have been set by a user. The user can set the voltages by counting the clock signal in steps using the counter 25, and then setting these different counter levels as predetermined voltages. Note that, instead of operating the circuit with the pre-set voltages, the user can reset the voltages as in the case of CR settings (FIGS. 22 and 23) to be described later.

As described above, the reference voltage generating circuit 21 outputs the reference voltage. The reference voltage is set beforehand in the reference voltage generating circuit 21 in such a manner that the pre-set voltage represented by the foregoing formula increases with time and reaches the target output voltage of the DC/DC converter by the time the initial operation of the charge pump operation is finished. By satisfying this condition, the user can freely decide when and how the voltage should be changed, taking also into account other conditions such as the desired effect of suppressing the in-rush current.

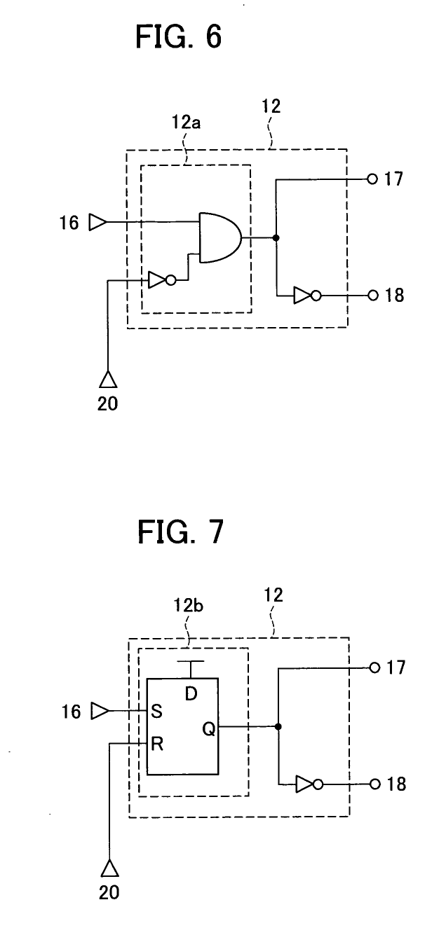

As shown in FIG. 6 or 7, the driving circuit 12 directly outputs the clock signal 16 as the first control signal 17, and an inverted signal of the clock signal 16 is outputted as the second control signal 18, provided that the deciding voltage 20 (described later) is not at H level. Thus, as long as the deciding voltage 20 is not H level, the first control signal 17 and the clock signal 16 have the same waveform of the opposite polarity.

In response to the clock signal 16, the driving circuit 12 outputs the first control signal 17 and the second control signal 18 with the voltage waveforms. Here, the driving circuit 12 performs logic operations with the output (deciding voltage) 20 of the feedback circuit 14 monitoring the output voltage 19. For this purpose, the driving circuit 12 is provided with a logic circuit and a latch circuit as shown in FIGS. 6 and 7.

More specifically, as shown in FIG. 6, a control section 12a serving as an OR circuit is inserted, and no clock signal 16 is supplied to the driving circuit 12 when the driving circuit 12 receives a target voltage detection signal (H level) as the pre-set signal 20. By adding the control section 12a to the driving circuit 12, an already existing charge pump DC/DC converter can have the function of suppressing the in-rush current.

FIG. 7 is another example of the control section for the driving circuit. In this example, a control section 12b serving as an SR flip-flop circuit is inserted. This enables the deciding timing to be synchronized with the clock signal 16.

In the examples illustrated in FIGS. 6 and 7, the control sections 12a and 12b are incorporated in the driving circuit 12. However, the control sections 12a and 12b may alternatively be provided as discrete circuits and connected to the driving circuit 12.

The following describes how the foregoing structure suppress the in-rush current caused by the current flowing into the bypass capacitor C13 between VIN and GND (current flown between the power supply VIN and the bypass capacitor) at the start of the charge pump operation.

With the foregoing structure of the present embodiment, the current generated at the start of the charge pump operation can be reduced. This is realized by (i) adding the feedback circuit 14 to the charge pump circuit, and (ii) controlling the voltage waveforms of the first and second control signals 17 and 18 and thereby suppressing the step-up time at the output terminal 15.

With the driving circuit 12, the clock signal 16 generated in the oscillating circuit 13 is outputted as the first and second control signals (first control signal 17, the second control signal 18) either directly or by being inverted. Upon receipt of the first and second control signals 17 and 18, the charge pump SW circuit 11 repeats the SW operation to operate as a charge pump. The feedback circuit 14 monitors the output voltage 19 in the manner described above, and constantly supplies the deciding signal (deciding voltage 20), indicative of whether the pre-set voltage has been reached, to the driving circuit 12. If the output voltage 19 has reached the pre-set voltage, the first and second control signals 17 and 18 from the driving circuit 12 are stopped to suspend the charge pump operation (charging operation for C12).

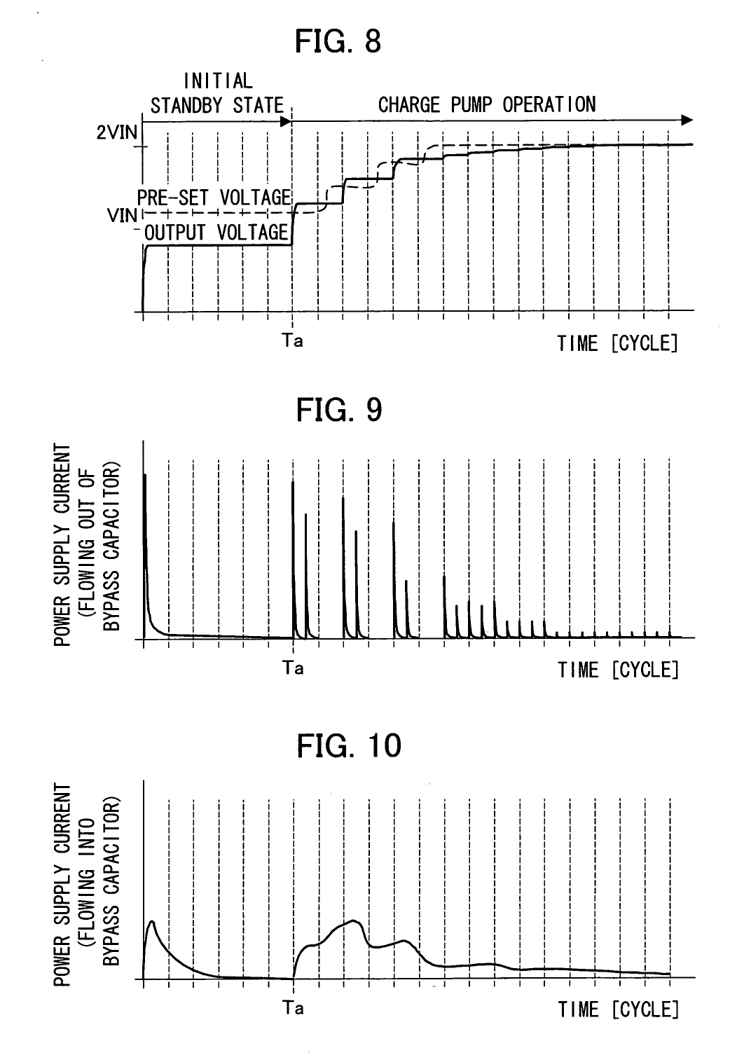

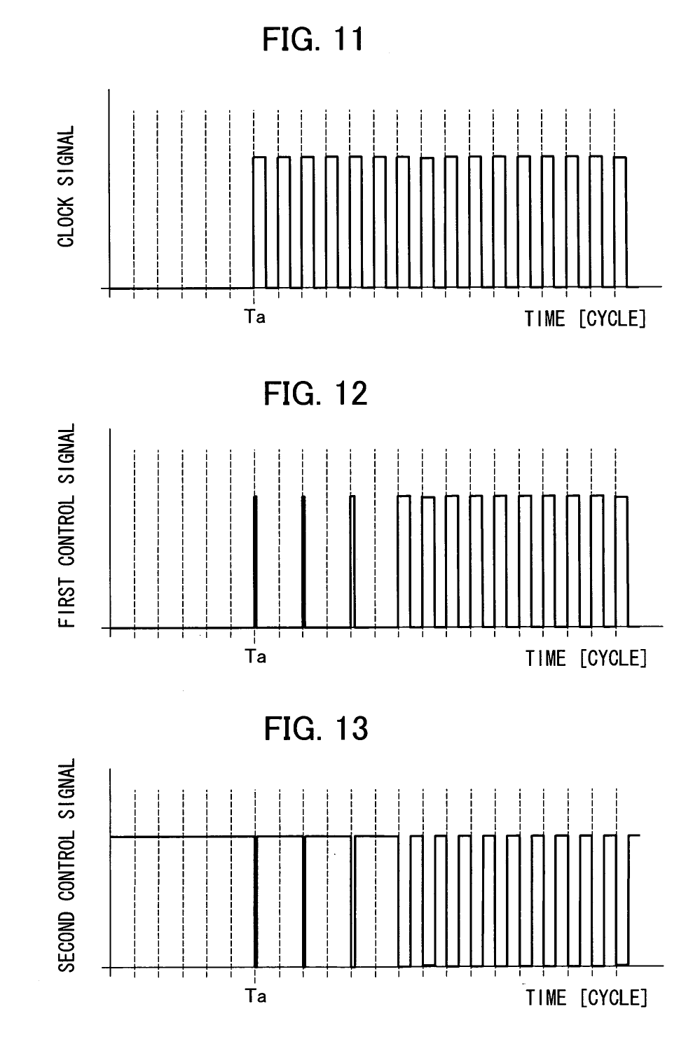

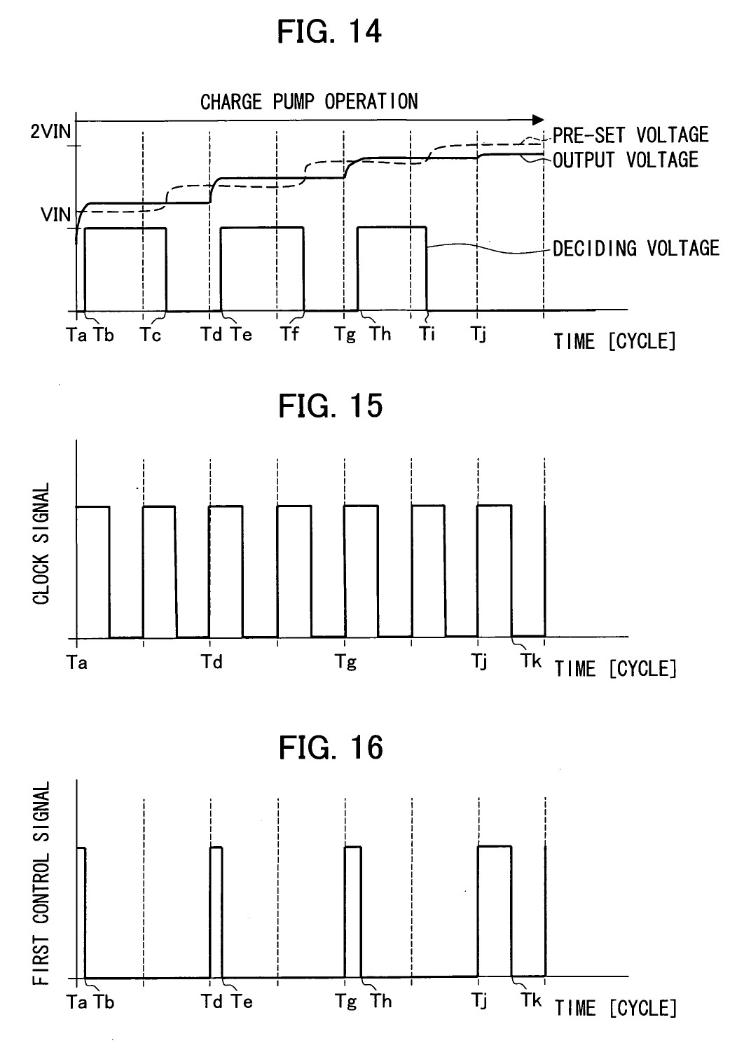

FIG. 8 represents a relationship between the pre-set voltage and the output voltage 19. FIGS. 9 and 10 represent examples of current waveforms. In FIG. 9, the legend “POWER SUPPLY CURRENT (FLOWN OUT OF BYPASS CAPACITOR)” refers to the current flowing through R2 shown in FIG. 3. In FIG. 10, the legend “POWER SUPPLY CURRENT (FLOWING INTO BYPASS CAPACITOR)” refers to the current flowing through R1 shown in FIG. 3. FIG. 11 represents an example of a voltage waveform of the clock signal. FIGS. 12 and 13 represent examples of voltage waveforms of the first and second control signals 17 and 18. FIGS. 14 through 17 are enlarged views in the vicinity of time Ta, which is the start time of the charge pump operation shown in FIGS. 8, 11, 12, and 13. As used herein, “the start of the charge pump operation” refers to the time at which the output capacitor C12 starts being charged by the charge pump operation. It should be noted here that these representations are based on the driving circuit with the control section of the structure depicted in FIG. 7. In the case of the driving circuit shown in FIG. 6, reference should be made to FIGS. 18 through 21, instead of FIGS. 14 through 17. The values of Ta through Tk are not related to one another between these two sets of drawings.

As shown in FIG. 14, the feedback circuit 14 allows charging of the output capacitor C12 when the output voltage 19 is below the pre-set voltage, and disallows charging of the output capacitor C12 when the output voltage 19 exceeds the pre-set voltage. To this end, the pre-set voltage is designed so that it increases with time, and reaches the target output voltage of the DC/DC converter by the time of initial operation of the charge pump operation is finished, as described above.

To describe more specifically, with the power supply voltage VIN at ON level, the charging current flows into the fly capacitor C11 and the output capacitor C12 via the parasitic diodes, causing the output voltage 19 to approach VIN. At this timing, the charging current flows into the power supply voltage VIN and the fly capacitor C11 and the output capacitor C12. The initial standby state is followed by the charge pump operation, in which the circuit current appears as the power supply current flowing out of the bypass capacitor C13. The power supply current is then averaged by the bypass capacitor C13 and appears as the power supply current that flows into the bypass capacitor C13.

With the pre-set voltage as shown in FIG. 8, the charge pump operation is performed when the output voltage 19 is below the pre-set voltage. Here, the charge pump operation itself is the same as the conventional charge pump operation.

Since the charge pump circuit 1 operates according to the first and second control signals 17 and 18 that are generated based on the clock signal 16, the step-up operation is controlled according to the deciding voltage 20 that is switched along with the pre-set voltage of the stepped waveform as shown in the waveform diagram.

That is, time Ta is the start time of the charge pump operation, or more specifically, the timing at which the output capacitor C12 starts being charged. Time Ta is also the time at which the output voltage 19 starts to increase. At time Tb, the output voltage 19 exceeds the pre-set voltage. Here, the output voltage 19 levels off to maintain its level. The pre-set voltage remains the same. At time Tc, the increasing pre-set voltage exceeds the output voltage 19. The output voltage 19 remains the same. Time Ta, Tb, and Tc are analogous to time Td, Te, and Tf, and time Tg, Th, and Ti, respectively.

Time Tj is analogous to Ta. At time Tk, the output voltage 19 levels off to maintain its level, as with time Tb.

The time periods between Ta and Tb, between Td and Te, and between Tg and Th are first through third H level periods of the first control signal 17. That is, these are time periods in which the output capacitor C12 is charged and the output voltage 19 rises. In the present embodiment, each of these time periods are controlled by the feedback circuit 14, so that it is shorter than half the cycle of the clock signal 16. At time Tk, unlike Tb, the output voltage does not exceed the pre-set voltage, i.e., the deciding voltage is not H level. As such, the time period between Tj and Tk is exactly half the cycle of the clock signal 16.

In this example, the curve of pre-set voltage is set so that the time period between Tg and Th is longer than the time period between Ta and Tb, or between Td and Te. Further, the pre-set voltage curve is set so that the time periods between Tb and Tc, Te and Tf, and Th and Ti are the same. However, these time periods may be related to one another in different patterns.

At time Ta, the deciding voltage 20 is at L level and the clock signal 16 rises. As a result, the output capacitor C12 is charged and the output voltage starts to increase.

When the output voltage 19 reaches the pre-set voltage at time Tb for example, the deciding voltage 20 is switched to H level with respect to the pre-set voltage, as shown in FIG. 14. As a result, the first and second control signals 17 and 18 are brought into the standby state (no charging to the output capacitor C12). Consequently, the charge of the fly capacitor C11 is no longer stored in the output capacitor C12, and the output voltage 19 is prevented from increasing and maintains its level until the next charging period of the output capacitor C12. In other words, the charge pump operation is suspended. The step-up operation is controlled in this manner.

When the operation resumes, the pre-set voltage rises at time Tc according to the predetermined settings. As a result, the pre-set voltage exceeds the output voltage 19 again. This brings the deciding voltage 20 to L level. However, because this is not the rising time of the clock signal 16, no charging operation is performed for the output capacitor C12.

At time Td, the clock signal 16 rises, with the deciding signal 20 maintained at L level. As a result, the charging operation of the output capacitor C12 is resumed.

The foregoing operations of from Ta to Td are repeated until the charging voltage for C12 (i.e., the output voltage) reaches the target voltage (here, 2VIN).

In this manner, the feedback circuit 14 controls the circuit operation at power-up (at the start of the charge pump operation), and thereby decreases the rate of increase of the output voltage. As a result, as shown in FIG. 10, the in-rush current averaged by the bypass capacitor C13 and originating from the power supply current (current flowing into the bypass capacitor C13 between VIN and GND) can be suppressed, which in turn suppresses the power supply peak current.

The following will describe how the waveforms as shown in FIG. 9 and FIG. 10 are produced for the power supply current flowing through R2 (flowing out of the bypass capacitor), and the power supply current flowing through R1 (flowing into the bypass capacitor), respectively. At the time when the transient current of the charge pump operation is supplied to the circuit-side VIN terminal via R2, R1 and C13 form a low-pass filter at the input of the charge pump DC/DC converter. Here, the time constant is determined by the wire resistance R1 and the capacitance of C13. As such, the charge is actually supplied from C13 to the charge pump DC/DC converter, and the charge lost by C13 is restored from VIN via R1.

The current required by the charge pump directly flows into R2, and therefore the current that flows through R2 has a waveform with narrow peaks as shown in FIG. 9. In FIG. 9, under feedback control, the current that flows through R2 is spread over time according to the operation timings. On the other hand, since the current that flows into R1 has been smoothed by the low-pass filter realized by R1 and C13, the current that flows through R1 has a waveform with wide peaks. In FIG. 10, the current flowing through R1 is continuous. This is because the charge pump operation is also continuous. In other words, the timings of the current that flows through R2 are spread out within a certain time period, so as to suppress the current that flows through the power supply VIN (R1).

As described above, in the present invention, the driving circuit is controlled while monitoring the output voltage 19 in the initial operation. This suppresses the current that flows between VIN and the bypass capacitor, and thereby suppresses the in-rush current in the initial operation of the charge pump circuit. As a result, adverse effects on other devices can be prevented.

Further, in the present invention, no additional circuit such as SW needs to be incorporated in the SW circuit of the charge pump in the charge pump DC/DC converter. As such, there is no new charge pump driving operation that needs to be controlled. There accordingly will be no adverse effect on the inherent characteristics of the charge pump.

According to the foregoing configuration, the circuit for reducing the in-rush current can be incorporated in the charge pump DC/DC converter. This can be done using the same method, regardless of the type, the number of stages, the driving method, and the like of the charge pump DC/DC converter. Further, since the control is performed according to the pre-set voltage set in the circuit, only the internal settings are required for the control, regardless of the external capacitor or the like.

In the operation example shown in FIG. 8, the charge pump circuit in the initial operation of the charge pump operation operates at half the frequency of the clock signal 16. Specifically, the stepwise increase of the output voltage 19 occurs once in every two cycles of the clock signal 16. In the operation example shown in FIG. 8, the charge pump circuit at the initial operation of the charge pump operation operates at the same frequency as the clock signal 16. That is, the output voltage 19 rises once in every cycle of the clock signal 16. However, the operating frequency is not just limited to these examples, and may not be constant. What is important is that the average current (in-rush current from the power supply) is effectively suppressed by controlling the time period between the initial operation and the normal operating state of the charge pump operation.

Further, in the foregoing examples, the pre-set voltage varies stepwise. However, in the case where the time control is performed based on C (capacitor) and R (resistor), the pre-set voltage forms a curve that is determined by the CR time constant.

For example, the reference voltage generating circuit for setting the reference voltage may have a structure as shown in FIG. 22 or 23. With this structure, the time required for the reference voltage to reach the internal reference voltage ref used as a target voltage is set based on time that is determined by the time constant of CR provided for the reference voltage. In such control using CR, as is well known, a resistor and a capacitor are used in combination, and the reference line to be controlled (output line to the comparator reference voltage) and GND are shorted by switching. This is performed before the initial operation so as to ensure the time control.

FIG. 22 illustrates a basic structure of the reference voltage generating circuit 22. In the reference voltage generating circuit 22, the time required for the reference voltage to reach the target voltage (internal reference voltage ref) is determined by the capacitor C and the resistor R. The pre-set value may be suitably set and stored in the circuit.

The reference voltage generating circuit (reference voltage varying and generating circuit) 23 shown in FIG. 23 is a modification of the circuit shown in FIG. 22. Within a pre-defined range set in the circuit, a user can vary the values of R and C to freely set the CR time constant. In this way, settings can be made that take into account peripheral components. In FIG. 23, the time constant is set with the variable resistor R. The variable resistor can be realized by disposing a resistor array and successively shorting the array by switching. Alternatively, the capacitor C may be variable.

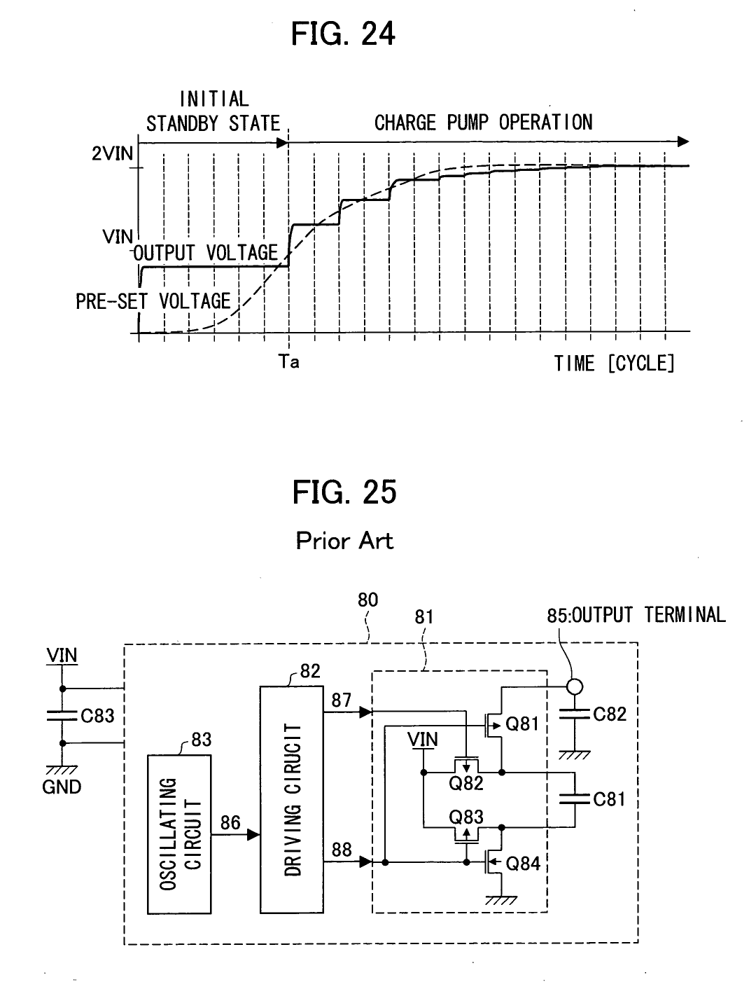

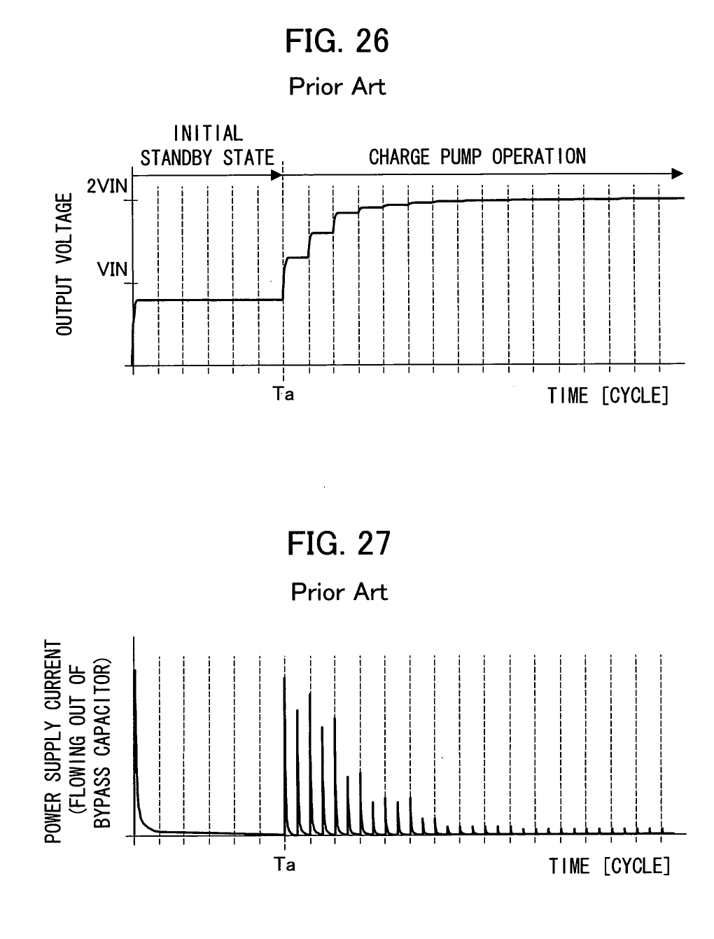

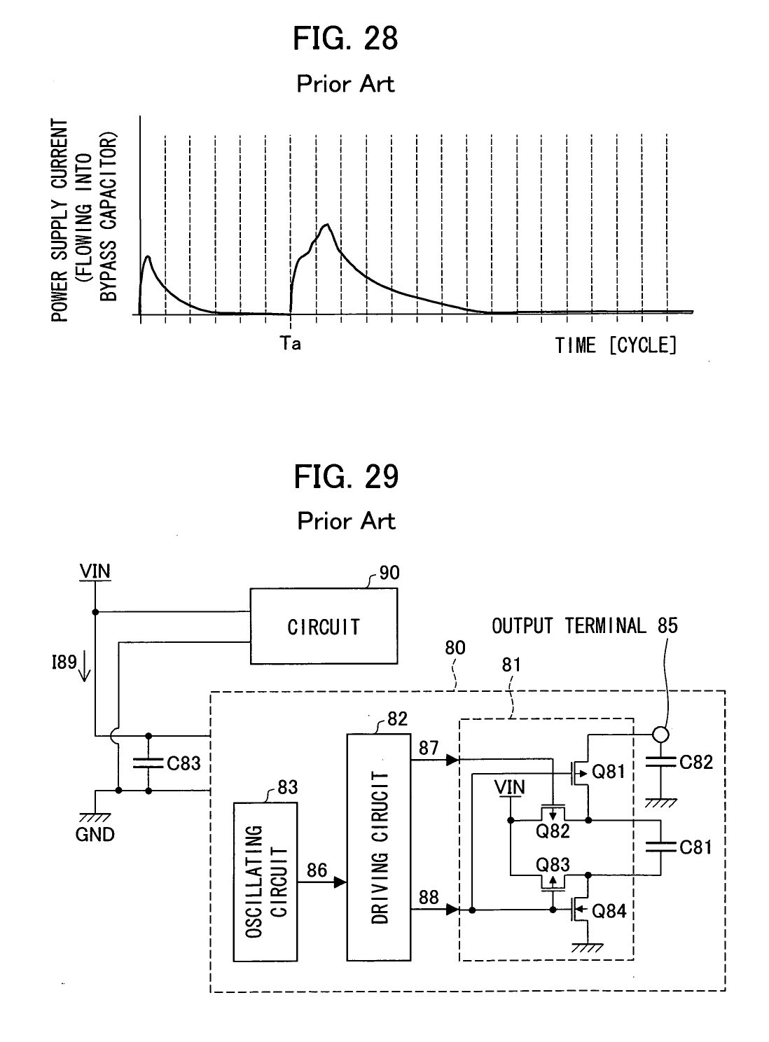

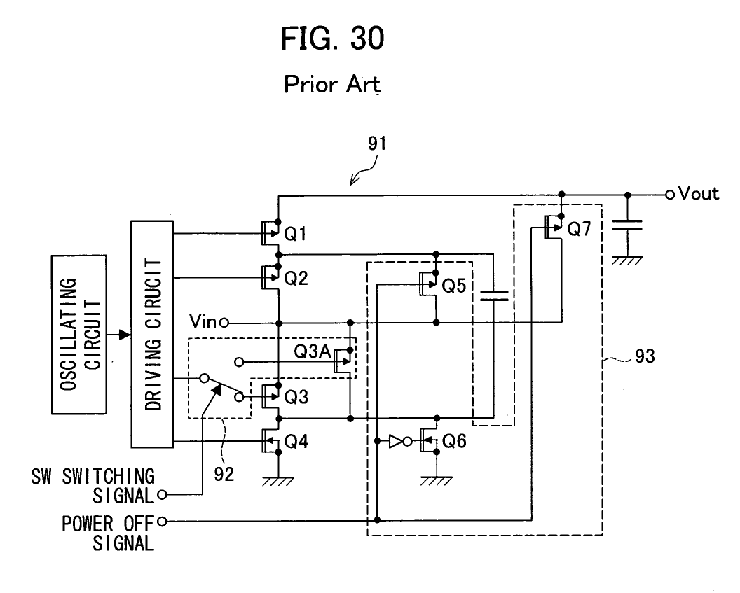

FIG. 24 represents an example of a waveform of the output voltage 19, and a waveform of the pre-set voltage. As shown in FIG. 24, in the time control using CR, the pre-set voltage forms a curve that is determined by the CR time constant. Here, the pre-set voltage gradually increases by forming a curve. This is different from the stepwise increase as shown in FIG. 8.

The present invention is not limited to the description of the embodiments above, but may be altered by a skilled person within the scope of the claims. An embodiment based on a proper combination of technical means disclosed in different embodiments is encompassed in the technical scope of the present invention.

A charge pump DC/DC converter according to the present invention may be adapted so that it includes a feedback system, and that a feedback pre-set voltage is controlled at power-up of the circuit.

Further, a charge pump DC/DC converter according to the present invention may be adapted so that the in-rush current is reduced irrespective of the number of stages, and the control method.

As described above, a charge pump DC/DC converter according to the present embodiment includes: a charge pump for charging an output capacitor to produce an output voltage; and a charging control circuit for allowing/disallowing charging of the output capacitor in an initial operation of a charge pump operation based on a predetermined pre-set voltage that increases with time and reaches a target output voltage level of the charge pump DC/DC converter by the time the initial stage of the charge pump operation is finished, wherein the charging control circuit allows charging of the output capacitor if the output voltage is below the pre-set voltage, and disallows charging of the output capacitor if the output voltage is above the pre-set voltage.

Thus, by setting a pattern of increase of the pre-set voltage during manufacture or use, the rate of increase of the output voltage can be reduced. In this way, the in-rush current during the initial operation of the charge pump operation can be reduced using a conventional charge pump DC/DC converter, without any modification to the circuit (charge pump SW (switch) circuit) portion provided with an output capacitor and a switching element for switching charging/discharging of the output capacitor in response to an inputted control signal (clock signal) for the output capacitor.

It is preferable that the charge pump DC/DC converter according to the present embodiment include a reference voltage varying and generating circuit for generating a reference voltage based on which the pre-set voltage is produced and with which a pattern of increase of the pre-set voltage is adjusted.

With this configuration, a pattern of increase of the voltage used to produce the pre-set voltage can be adjusted. In this way, it is possible to accommodate changes in the devices attached to the output terminal, or changes in various elements (peripheral components) provided in the charge pump DC/DC converter. Thus, in addition to the foregoing effect, the charge pump operation can be performed both easily and desirably even when there is a change in the peripheral components.

Further, it is preferable in the charge pump DC/DC converter according to the present embodiment that the charging control circuit compare the output voltage with the pre-set voltage by comparing a comparative voltage with increasing values of a reference voltage, where the comparative voltage is a voltage of a point with a predetermined potential difference ΔV from the output voltage, and the reference voltage is a voltage with the same predetermined potential difference ΔV from the pre-set voltage.

With this configuration, a comparison is made between a comparative voltage, which is a voltage of a point with a predetermined potential difference ΔV from the output voltage, and a reference voltage, which is a voltage with the same predetermined potential difference ΔV from the pre-set voltage. For example, a large value can be set for ΔV for products producing a large output voltage, and a small value can be set for ΔV for products producing a small output voltage. By thus adjusting ΔV during manufacture, modification to the circuit itself generating the reference voltage needs to be made less often. Thus, in addition to the foregoing effects, the charge pump DC/DC converter can accommodate various forms.

It is preferable in the charge pump DC/DC converter of the present embodiment that the comparative voltage be smaller than the output voltage.

With this configuration, since the comparative voltage is smaller than the output voltage, no large reference voltage needs to be produced. Thus, in addition to the foregoing effects, power consumption can be reduced.

Further, it is preferable that the charge pump DC/DC converter according to the present embodiment include a driving circuit for supplying the charge pump with a control signal for driving the charge pump, the driving circuit supplying the control signal based on a deciding voltage signal, indicative of whether the output voltage is below the pre-set voltage, generated by the charge control circuit.

Further, it is preferable in the charge pump DC/DC converter according to the present embodiment that the driving circuit supply the control signal to the charge pump when the deciding voltage signal indicates that the output voltage is below the pre-set voltage, and that the driving circuit stop supplying the control signal to the charge pump when the deciding voltage signal indicates that the output signal is at or above the pre-set voltage.

Further, it is preferable that the charge pump DC/DC converter according to the present embodiment include an oscillating circuit for generating a clock signal, wherein the driving circuit supplies the control signal to the charge pump based on the clock signal generated by the oscillating circuit.

Further, it is preferable in the charge pump DC/DC converter according to the present embodiment that the charging control circuit compare a comparative voltage, which is based on the output voltage, with a reference voltage, which is based on the pre-set voltage, so as to generate a deciding voltage signal indicative of whether the output voltage is below the pre-set voltage.

Further, it is preferable that the charge pump DC/DC converter according to the present embodiment include a reference voltage varying and generating circuit for generating the reference voltage, wherein the reference voltage varying and generating circuit includes: a counter for counting the clock signal; and a selector for selecting and supplying the reference voltage to the charging control circuit based on the clock signal counted by the counter.

Further, it is preferable that the charge pump DC/DC circuit according to the present embodiment include a reference voltage varying and generating circuit for generating a reference voltage that increases stepwise with time, and supplying the reference voltage to the charging control circuit.

Further, it is preferable that the charge pump DC/DC converter according to the present embodiment include a reference voltage varying and generating circuit for generating a reference voltage that increases continuously with time, and supplying the reference voltage to the charging control circuit.

Further, it is preferable in the charge pump DC/DC converter according to the present embodiment that the pre-set voltage increase stepwise with time.

Further, it is preferable in the charge pump DC/DC converter according to the present embodiment that the pre-set voltage increase continuously with time.

The present invention suppresses the in-rush current that occurs during the initial operation of the charge pump operation, and therefore prevents adverse effects on other devices. The invention is therefore applicable to charge pump DC/DC converters, for example.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A charge pump DC/DC converter comprising:
a charge pump for charging an output capacitor to produce an output voltage; and
a charging control circuit for allowing/disallowing charging of the output capacitor in an initial operation of a charge pump operation based on a predetermined pre-set voltage that increases with time and reaches a target output voltage level of the charge pump DC/DC converter by the time the initial operation of the charge pump operation is finished, wherein the charging control circuit allows charging of the output capacitor if the output voltage is below the pre-set voltage, and disallows charging of the output capacitor if the output voltage is above the pre-set voltage.

2. The charge pump DC/DC converter as set forth in claim 1, further comprising a reference voltage varying and generating circuit for generating a reference voltage based on which the pre-set voltage is produced and with which a pattern of increase of the pre-set voltage is adjusted.

3. The charge pump DC/DC converter as set forth in claim 1, wherein the charging control circuit compares the output voltage with the pre-set voltage by comparing a comparative voltage with increasing values of a reference voltage, where the comparative voltage is a voltage of a point with a predetermined potential difference ΔV from the output voltage, and the reference voltage is a voltage with the same predetermined potential difference ΔV from the pre-set voltage.

4. The charge pump DC/DC converter as set forth in claim 3, wherein the comparative voltage is smaller than the output voltage.

5. The charge pump DC/DC converter as set forth in claim 1, further comprising a driving circuit for supplying the charge pump with a control signal for driving the charge pump, the driving circuit supplying the control signal based on a deciding voltage signal, indicative of whether the output voltage is below the pre-set voltage, generated by the charge control circuit.

6. The charge pump DC/DC converter as set forth in claim 5, wherein the driving circuit supplies the control signal to the charge pump when the deciding voltage signal indicates that the output voltage is below the pre-set voltage, and the driving circuit stops supplying the control signal to the charge pump when the deciding voltage signal indicates that the output signal is at or above the pre-set voltage.

7. The charge pump DC/DC converter as set forth in claim 5, further comprising an oscillating circuit for generating a clock signal,
wherein the driving circuit supplies the control signal to the charge pump based on the clock signal generated by the oscillating circuit.

8. The charge pump DC/DC converter as set forth in claim 1, wherein the charging control circuit compares a comparative voltage, which is based on the output voltage, with a reference voltage, which is based on the pre-set voltage, so as to generate a deciding voltage signal indicative of whether the output voltage is below the pre-set voltage.

9. The charge pump DC/DC converter as set forth in claim 8, further comprising a reference voltage varying and generating circuit for generating the reference voltage,
wherein the reference voltage varying and generating circuit includes:
a counter for counting a clock signal; and
a selector for selecting and supplying the reference voltage to the charging control circuit based on the clock signal counted by the counter.

10. The charge pump DC/DC circuit as set forth in claim 8, further comprising a reference voltage varying and generating circuit for generating a reference voltage that increases stepwise with time, and supplying the reference voltage to the charging control circuit.

11. The charge pump DC/DC converter as set forth in claim 8, further comprising a reference voltage varying and generating circuit for generating a reference voltage that increases continuously with time, and supplying the reference voltage to the charging control circuit.

12. The charge pump DC/DC converter as set forth in claim 1, wherein the pre-set voltage increases stepwise with time.

13. The charge pump DC/DC converter as set forth in claim 1, wherein the pre-set voltage increases continuously with time.
